(19) United States
(12) Patent Application Publication
(10) Pub. No.: US 2026/0040503 A1
(43) Pub. Date: Feb. 5, 2026

(54) COOLING ARRANGEMENTS FOR AUTONOMOUS RACKS

(71) Applicant: OVH, Roubaix (FR)

(72) Inventors: Hadrien BAUDUIN, Villeneuve d’Ascq (FR); Ali CHEHADE, Moncheaux (FR); Mahdi VAHIDI FERDOUSI, Lille (FR)

(21) Appl. No.: 19/285,957

(22) Filed: Jul. 30, 2025

(30) Foreign Application Priority Data
Aug. 2, 2024 (EP) 24306322.9

(51) Int. Cl. H05K 7/20

(52) U.S. Cl. CPC H05K 7/20818; H05K 7/20327

(57) ABSTRACT

Autonomous rack system configurations for datacenter operations are presented that include a combination of a first rack structure incorporating front-mounted heat exchanger and a second rack structure incorporating a rear-mounted heat exchanger, such that liquid-cooled heat-generating electronic components that are less tolerant to higher temperatures are disposed within the first rack structure and liquid-cooled heat-generating electronic components that are more tolerant to higher temperatures are disposed within the second rack structure. These configurations utilize the residual air flow that passes through the less temperature tolerant electronic components of the first rack structure and redirect it to the second rack structure to cool the more temperature tolerant electronic components of the second rack structure.

### CROSS-REFERENCE

The present application claims priority to European Patent Application No. 24306322 filed on Aug. 2, 2024, and entitled “COOLING ARRANGEMENTS FOR AUTONOMOUS RACKS”, the entirety of which is incorporated herein by reference.

### FIELD

The present technology relates to cooling techniques for electronic equipment. In particular, a cooling arrangement for autonomous racks.

### BACKGROUND

Electronic equipment, for example servers, memory banks, computer discs, and the like, are conventionally grouped in equipment racks. Large data centers and other large computing facilities may contain thousands of racks supporting thousands or even tens of thousands of server racks.

The server racks consume large amounts of electric power and generate significant amounts of heat. Cooling needs are important in such racks. Indeed, some electronic devices, such as newer generation processors, operate at computation speeds that produce so much heat that they could fail within seconds in cases of inadequate cooling.

To address this heating issue, datacenter server racks mount fans on the backplanes of server racks that generate forced ventilation to extract heated air from the server racks and expel the heated air into the ambient environment. While this configuration provides some relief in various applications, other measures have been employed to assist in the further cooling of server racks.

For example, liquid cooling circulatory measures (i.e., “liquid cooling loops”) including liquid cooling blocks/units and/or air-to-liquid heat exchangers, have been employed into the server racks to absorb and redirect some of the expelled heat to further cooling equipment, such as, for example, cooling towers, located outside of the data center. Mainly the use of liquid cooling wit liquid cooling blocks (i.e., “direct-to-chip liquid cooling”) has proven it provides better cooling performance and allows greater server racks power density.

However, there is also a need to provide autonomous racks having self-contained liquid cooling loops that are capable of being installed in environments that lack liquid cooling infrastructures while benefiting from liquid cooling blocks to service the overall cooling needs of server racks.

Even though the recent developments identified above may provide benefits, improvements are still desirable for autonomous rack implementations.

The subject matter discussed in the background section should not be assumed to be prior art merely as a result of its mention in the background section. Similarly, a problem mentioned in the background section or associated with the subject matter of the background section should not be assumed to have been previously recognized in the prior art. The subject matter in the background section merely represents different approaches.

### SUMMARY

Embodiments of the present technology are a result of developers' appreciation and study of the shortcomings associated with the prior art. In particular, such shortcomings may comprise difficulties in optimizing the cooling of components within autonomous racks.

With this said, an aspect of the present technology provides an autonomous rack system that comprises a first rack structure housing a first set of rack-mounted processing assemblies containing liquid-cooled heat-generating electronic components and air-cooled heat-generating electronic components, the first rack structure having a front side and an opposing rear side; a first air-to-liquid heat exchanger mounted to the front side of the first rack structure and configured to pull in cold ambient air towards the first set of rack-mounted processing assemblies; a first liquid cooling loop, comprising: a circulation conduit conveying cooling liquid incorporating a forward path fluidly-coupled to an output of the first air-to-liquid heat exchanger and a return path fluidly-coupled to an input of the first air-to-liquid heat exchanger; at least one liquid cooling unit thermally mounted onto the at least one liquid-cooled heat-generating electronic component of the first set of processing assemblies and fluidly-coupled to the circulation conduit to internally channel the cooling liquid therethrough; and at least one first pump to forcibly urge the flow of the cooling liquid through the forward path, the liquid cooling unit, the return path, and the first air-to-liquid heat exchanger.

Given this configuration, the cold ambient air pulled into the front side of the first rack structure by the first air-to-liquid heat exchanger is firstly warmed while cooling the first cooling liquid, flows across the first set of processing assemblies, such that the air secondly warmed by the air-cooled heat-generating electronic components of the first set of processing assemblies is expelled from the rear side of the first rack structure; along the forward path, the liquid cooling unit receives the cooling liquid from the output of the first air-to-liquid heat exchanger for internally channeling the cooling liquid therein; and along the return path the liquid cooling unit returns the internally channeled liquid after being warmed by the liquid-cooled heat-generating electronic components of the first set of processing assemblies to the input of the first air-to-liquid heat exchanger.

An additional related aspect further includes a second rack structure juxtaposedly positioned at the rear of the first rack structure, the second rack structure housing a second set of rack-mounted processing assemblies containing air-cooled heat-generating electronic components, and liquid-cooled heat-generating electronic components having operating thermal requirements that are more tolerant to higher temperature levels than the liquid-cooled heat-generating electronic components of the first set of rack-mounted processing assemblies; a second air-to-liquid heat exchanger mounted to the rear side of the second rack structure and configured to pull away warmed air from the second set of rack-mounted processing assemblies and expel the hot air from the rear side of the second rack structure; a second liquid cooling loop, comprising: a circulation conduit conveying cooling liquid incorporating a forward path fluidly-coupled to an output of the second air-to-liquid heat exchanger and a return path fluidly-coupled to an input of the second air-to-liquid heat exchanger; at least one liquid cooling unit thermally mounted onto the at least one liquid-cooled heat-generating electronic component of the second set of processing assemblies and fluidly-coupled to the circulation conduit to internally channel the cooling liquid; and at least one second pump to forcibly urge the flow of the cooling liquid through the forward path, the liquid cooling unit, the return path, and the second air-to-liquid heat exchanger.

According to this related aspect, warm air is expelled from the first set of processing assemblies flows across the second set of rack-mounted processing assemblies, such that the air warmed-up by the air-cooled heat-generating components of the second set of rack-mounted processing assemblies is expelled from the rear side of the second rack structure by the second air-to-liquid heat exchanger, where the expelled air gets warmer while cooling the second cooling liquid; the second cooling liquid of the second liquid cooling loop is warmer than the first cooling liquid of the first liquid cooling loop; along the forward path, the liquid cooling unit receives the liquid from the output of the second air-to-liquid heat exchanger for internally channeling the liquid therein; and along the return path, the liquid cooling unit returns the internally channeled liquid after being warmed by the liquid-cooled heat-generating electronic components of the second set of processing assemblies to the input of the second air-to-liquid heat exchanger

Another aspect of the present technology provides an autonomous rack system, comprising: a rack structure housing a first set of rack-mounted processing assemblies containing liquid-cooled heat-generating electronic components and air-cooled heat-generating electronic components and a second set of rack-mounted processing assemblies containing air-cooled heat-generating electronic components and liquid-cooled heat-generating electronic components having operating thermal requirements that are more tolerant to higher temperature levels than the liquid-cooled heat-generating electronic components of the first set of rack-mounted processing assemblies; a first air-to-liquid heat exchanger mounted to a front side of the rack structure and configured to pull in cold ambient air towards the first set of rack-mounted processing assemblies; a second air-to-liquid heat exchanger mounted to a rear side of the rack structure and configured to pull away warmed air from the second set of rack-mounted processing assemblies and expel the hot air from the rear side of the rack structure; a first liquid cooling loop, comprising: a first circulation conduit conveying cooling liquid incorporating a forward path fluidly-coupled to an output of the first air-to-liquid heat exchanger and a return path fluidly-coupled to an input of the first air-to-liquid heat exchanger; at least one liquid cooling unit thermally mounted onto the at least one liquid-cooled heat-generating electronic component of the first set of processing assemblies and fluidly-coupled to the circulation conduit to internally channel the cooling liquid therethrough; and at least one first pump to forcibly urge the flow of the cooling liquid through the forward path, the liquid cooling unit, the return path, and the first air-to-liquid heat exchanger; a second liquid cooling loop, comprising: a second circulation conduit conveying cooling liquid incorporating a forward path fluidly-coupled to an output of the second air-to-liquid heat exchanger and a return path fluidly-coupled to an input of the second air-to-liquid heat exchanger; at least one liquid cooling unit thermally mounted onto the at least one liquid-cooled heat-generating electronic component of the second set of processing assemblies and fluidly-coupled to the circulation conduit to internally channel the cooling liquid therethrough; and at least one second pump to forcibly urge the flow of the cooling liquid through the forward path, the liquid cooling unit, the return path, and the second air-to-liquid heat exchanger.

In this configuration, the cold ambient air pulled into the front side of the rack structure by the first air-to-liquid heat exchanger, is firstly warmed while cooling the first cooling liquid of the first liquid cooling loop and flows across the first and second sets of processing assemblies, such that the air warmed by the air-cooled heat-generating electronic components of the first and second sets of processing assemblies is expelled from the rear side of the rack structure by the second air-to-liquid heat exchanger, where the expelled air gets warmer while cooling the second cooling liquid of the second liquid cooling loop; the second cooling liquid of the second liquid cooling loop is warmer than the first cooling liquid of the first liquid cooling loop; along the forward path of the first circulation conduit, the liquid cooling unit receives the cooling liquid from the output of the first air-to-liquid heat exchanger for internally channeling the cooling liquid therein and along the return path, the liquid cooling unit returns the internally channeled liquid after being warmed by the liquid-cooled heat-generating electronic components of the first set of processing assemblies to the input of the first air-to-liquid heat exchanger; and along the forward path of the second circulation conduit, the liquid cooling unit receives the cooling liquid from the output of the second air-to-liquid heat exchanger for internally channeling the cooling liquid therein and along the return path, the liquid cooling unit returns the internally channeled liquid after being warmed by the liquid-cooled heat-generating electronic components of the second set of processing assemblies to the input of the second air-to-liquid heat exchanger.

With this said, within the context of the present specification, unless expressly provided otherwise, electronic equipment may refer, but is not limited to, “servers”, “electronic devices”, “operation systems”, “systems”, “computer-based systems”, “controller units”, “monitoring devices”, a “control devices” and/or any combination thereof appropriate to the relevant task at hand.

Additionally, within the context of the present specification, unless expressly provided otherwise, the words “first”, “second”, “third”, etc. have been used as adjectives only for the purpose of allowing for distinction between the nouns that they modify from one another, and not for the purpose of describing any particular relationship between those nouns.

Implementations of the present technology each have at least one of the above-mentioned objects and/or aspects, but do not necessarily have all of them. It should be understood that some aspects of the present technology that have resulted from attempting to attain the above-mentioned object may not satisfy this object and/or may satisfy other objects not specifically recited herein.

Additional and/or alternative features, aspects and advantages of implementations of the present technology will become apparent from the following description, the accompanying drawings and the appended claims.

### BRIEF DESCRIPTION OF THE DRAWINGS

For a better understanding of the present technology, as well as other aspects and further features thereof, reference is made to the following description which is to be used in conjunction with the accompanying drawings, where:

FIG. 1 is a schematic diagram of a side view of an autonomous server rack incorporating a front-mounted heat exchanger, in accordance with the embodiments of the present disclosure;

FIG. 2 is a schematic diagram of a side view of an autonomous dual server rack incorporating a front-mounted heat exchanger and a rear-mounted heat exchanger, as well as a front-loading server sub-rack and a rear-loading server sub-rack, in accordance with the embodiments of the present disclosure;

FIGS. 3A, 3B depict schematic side views of a datacenter room for accommodating two different server rack configurations, in accordance with the embodiments of the present disclosure; and

FIG. 4 is a schematic diagram of a side view of an autonomous server rack configuration incorporating a front-mounted heat exchanger and a rear-mounted heat exchanger, in accordance with the embodiments of the present disclosure; and

FIG. 5 is a schematic diagram of a side view of an another autonomous server rack configuration similar to the autonomous server rack configuration incorporating a front-mounted heat exchanger and a rear-mounted heat exchanger, in accordance with the embodiments of the present disclosure.

It should be understood that, unless otherwise explicitly specified herein, the drawings are not to scale.

### DETAILED DESCRIPTION

The examples and conditional language recited herein are principally intended to aid the reader in understanding the principles of the present technology and not to limit its scope to such specifically recited examples and conditions. It will be appreciated that those skilled in the art may devise various arrangements that, although not explicitly described or shown herein, nonetheless embody the principles of the present technology.

Furthermore, as an aid to understanding, the following description may describe relatively simplified implementations of the present technology. As persons skilled in the art would understand, various implementations of the present technology may be of a greater complexity.

In some cases, what are believed to be helpful examples of modifications to the present technology may also be set forth. This is done merely as an aid to understanding, and, again, not to define the scope or set forth the bounds of the present technology. These modifications are not an exhaustive list, and a person skilled in the art may make other modifications while nonetheless remaining within the scope of the present technology. Further, where no examples of modifications have been set forth, it should not be interpreted that no modifications are possible and/or that what is described is the sole manner of implementing that element of the present technology.

Moreover, all statements herein reciting principles, aspects, and implementations of the present technology, as well as specific examples thereof, are intended to encompass both structural and functional equivalents thereof, whether they are currently known or developed in the future.

An aspect of the present technology introduces a cooling arrangement for autonomous cooling of a rack, for example a server rack, hosting at least one liquid-cooled heat generating component, at least one air-cooled heat-generating component and at least one fan. The cooling arrangement comprises a closed loop and an open loop. The closed loop provides liquid cooling for the liquid-cooled heat-generating component. The open loop provides air cooling for the air-cooled heat-generating component with the at least one fan pulling fresh air from the front of the server rack and expelling heated air to the rear of the server rack. A liquid, for example water, is initially fed to the closed loop, and while circulating therein, is brought to a hotter temperature by the heat exhausted by the liquid-cooled heat-generating component. The hotter liquid is then circulated within an air-to-liquid heat exchanger at a junction between the open loop and the closed loop. The hotter liquid of the closed loop is cooled by thermal transfer from the closed loop to the open loop in the air-to-liquid heat exchanger. The cooler liquid from the closed loop is recirculated back for recooling the liquid-cooled heat-generating component. The air from the open loop, which has increased in temperature, is expelled from the open loop for an exterior exhaust and/or treatment.

With these fundamentals in place, we will now consider some non-limiting examples to illustrate various implementations of aspects of the present technology.

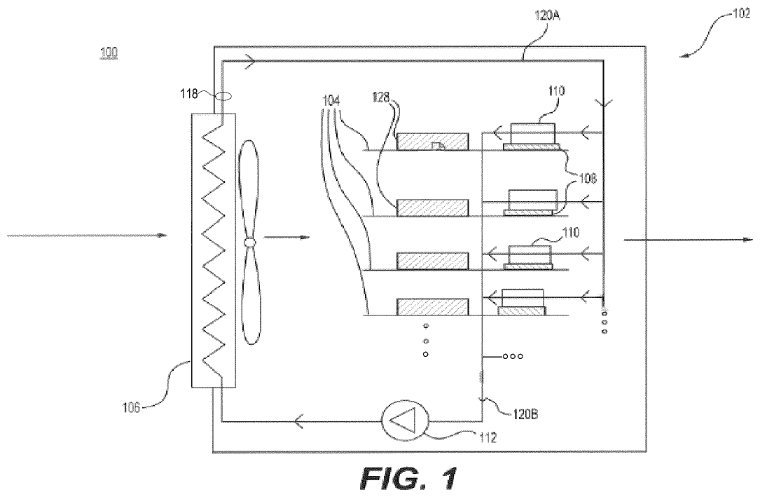

FIG. 1 is a schematic diagram of a side view of an autonomous server rack configuration 100 incorporating a front-mounted heat exchanger, in accordance with the embodiments of the present disclosure. As shown, autonomous server rack configuration 100 comprises a first rack structure 102 housing a first set of rack-mounted processing assemblies 104 containing liquid-cooled heat-generating electronic components 108 and air-cooled heat-generating electronic components 128. In certain operations, such liquid-cooled heat-generating electronic components 108 may be more sensitive to (i.e., less tolerant of) high temperature levels and require optimal cooling with low coolant temperatures. For example, some temperature sensitive electronic components 108 may require liquid inlet temperature to be approximately <35° C. and/or liquid outlet temperature approximately <40° C.

To service the cooling needs of these liquid-cooled heat-generating electronic components 108, unlike conventional rack installations, the autonomous server rack configuration 100 incorporates a first air-to-liquid heat exchanger 106 mounted on a front side of the rack structure 102 and equipped with at least one fan. That is, conventional rack installations mount air-to-liquid heat exchangers on a rear side of the rack to cool the cooling liquid with warm air, and extract heated air away from the rack and expel into ambient environment (hot ambient air, typically in a “hot aisle” to be expelled or retreated/recooled by the conventional data center infrastructure). However, the first front-mounted heat exchanger 106 serves to pull in cold ambient air to increase the air-to-liquid cooling capacity thereof, cool the cooling liquid heated by the liquid-cooled heat-generating electronic components 108, and distribute the slightly warmed air throughout the rack. Typically, cold ambient air is pulled from a “cold aisle” wherein air temperature is comprised between around 24° C. and 27° C. The detailed configuration may work up to cold ambient air temperature around 32° C. As such, air firstly warmed by flowing across the air-to-liquid heat exchanger is still at sufficiently low temperature (e.g., does not exceed 30° C. to 37° C.) to cool the air-cooled heat-generating electronic components 128. The air secondly warmed is subsequently expelled away through a rear side of the rack structure 102.

The front-mounted heat exchanger 106 is equipped with an input (not shown) for receiving warm liquid from the liquid-cooled heat-generating electronic components 108 and an output (not shown) for forwarding recooled liquid back to the liquid-cooled heat-generating electronic components 108. In certain embodiments, air-to-liquid heat exchanger 106 may be embodied as a finned heat exchanger (FHEX). In certain embodiments, air-to-liquid heat exchanger 106 is part of a front door (e.g., front door heat exchanger, as opposed to conventional rear door heat exchanger), equipped, for example, with hinges.

Moreover, the first front-mounted heat exchanger 106 is fluidly-coupled to a first liquid cooling loop 118 comprising a first circulation conduit 120 that conveys cooling liquid. In particular, the first circulation conduit 120 comprises a forward path 120A fluidly-coupled to the output of the first front-mounted heat exchanger 106 for forwarding cool/recooled liquid to the liquid-cooled heat-generating electronic components 108 and a return path 120B fluidly-coupled to the input of the first front-mounted heat exchanger 106 for receiving warmed liquid from the liquid-cooled heat-generating electronic components 108 for recooling operations thereby.

As such, the first liquid cooling loop 118 is fluidly-coupled to at least one liquid cooling unit 110 that is thermally-mounted on a corresponding liquid-cooled heat-generating electronic component 108. The liquid cooling unit 110 is configured with a continuous internal channel that allows for the passage of cooling liquid therethrough.

The autonomous server rack configuration 100 further incorporates at least one pump 112 to forcibly urge the flow of the cooling liquid along the forward path 120A for supplying the at least one liquid cooling unit 110 with cool/recooled liquid and for urging the flow of warmed liquid along the return path 120B back to the first air-to-liquid heat exchanger 106 for recooling operations. In certain cases, two or more pumps may be implemented and may be arranged in series or parallel configurations. In some embodiments, there is a plurality of liquid cooling units 110 and the forward path 120A and return path 120B include cooling distribution units to fluidly-couple in parallel the liquid cooling units 110 or with a combination of series and parallel arrangement.

In some embodiments, the first rack structure 102 of the autonomous server rack configuration 100 is mechanically divided into a plurality of vertical columns horizontally or vertically adjacent, and the first front-mounted heat exchanger 106 is a plurality of first front-mounted heat exchangers 106. For example, in some cases, the first rack structure 102 may be arranged with three horizontally adjacent vertical columns, each of them being equipped with a first front-mounted heat exchanger 106, with the three front-mounted heat exchangers 106 being fluidly connected in a parallel configuration.

In this manner, the autonomous server rack configuration 100 provides a cooling configuration that optimizes, both air cooling and liquid cooling measures for liquid-cooled heat-generating electronic components 108 and air-cooled heat-generating electronic components 128. Firstly, the first front-mounted air-to-liquid heat exchanger 106 operates to pull in cold ambient air into the front side of the first rack structure 102, thus, front mounted air-to-liquid heat exchanger 106 increases its capacity for recooling warmed liquid received from the liquid-cooled heat-generating electronic components 108 and forward the recooled liquid back to the liquid-cooled heat-generating electronic components 108 via the first liquid cooling loop 118. Secondly, air firstly warmed flows across the first set of processing assemblies 104 at sufficiently low temperature for cooling the air-cooled heat-generating electronic components 128. In other words, as opposed to the conventional configuration with rear-mounted heat exchanger, liquid cooling is optimized performance-wise by working at lower liquid temperatures, and air cooling is optimized energy efficient-wise by working at higher air temperature—while still complying with electronics thermal requirements.

In some embodiments, the air and liquid temperatures of the autonomous server rack configuration 100, as well as the temperature of the heat-generating electronic components 108 and 128 are monitored. In such embodiments, the rotation speed of fans mounted on the heat exchanger 106 and the rotation speed of pump 112 are controlled to deliver the right flow rates for reaching adapted cooling fluid temperatures and optimizing the cooling of the heat-generating electronic components 108 and 128. Besides, in such embodiments, energy usage efficiency may be optimized.

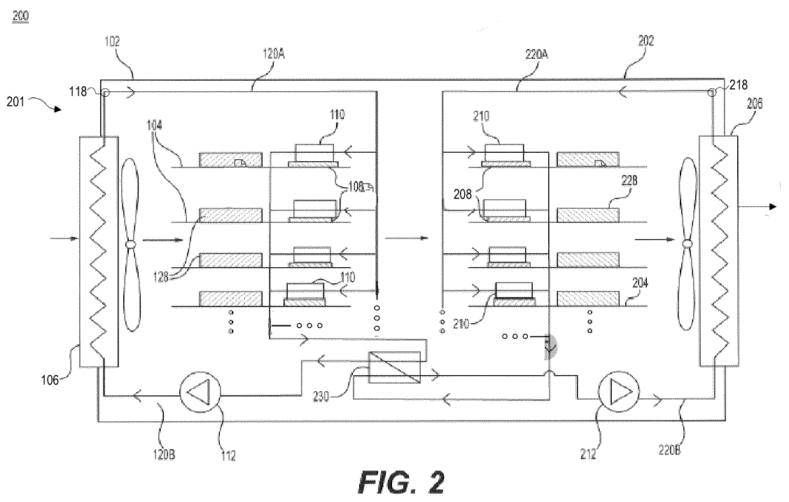

In a related embodiment, FIG. 2 is a schematic diagram of a side view of an autonomous dual server rack configuration 200 incorporating a front-mounted heat exchanger and a rear-mounted heat exchanger, in accordance with the embodiments of the present disclosure.

The autonomous dual server rack configuration 200 exploits the advantages of the autonomous server rack configuration 100 noted above to extend the operations thereof to a dual server rack structure 201 that efficiently handles the cooling needs of heat-generating electronic components with different thermal requirements.

As shown, autonomous dual server rack configuration 200 comprises a rack structure 201 that combines two autonomous server racks 102, 202 disposed in back-to-back fashion. Specifically, the first autonomous server rack 102, as described above relative to the autonomous server rack configuration 100, is positioned at the front side of the rack structure 201 while the second autonomous server rack 202 is juxtaposedly positioned at the rear side of the first autonomous server rack 102. The second autonomous server rack 202 houses a second set of rack-mounted processing assemblies 204 containing liquid-cooled heat-generating electronic components 208 and air-cooled heat-generating electronic components 228. For purposes of brevity and tractability, the noted component operations of the first autonomous server rack 102 detailed above, will not be repeated unless such components bear on the overall operations of the autonomous dual server rack 200.

The autonomous dual server rack configuration 200 is designed to service the cooling needs of liquid-cooled heat-generating electronic components 108 that are less tolerant of higher operating temperature levels requiring optimal cooling measures as well as service the cooling needs of liquid-cooled heat-generating electronic components 208 that are more tolerant to higher operating temperature levels requiring adequate cooling measures.

With this said, the autonomous dual server rack configuration 200 installs the liquid-cooled heat-generating electronic components 108 that require optimal cooling measures in the first autonomous server rack 102 of the dual server rack structure 201. As noted above, the first autonomous server rack 102 employs a first front-mounted air-to-liquid heat exchanger 106 to pull in cold ambient air to cool the cooling liquid heated by the liquid-cooled heat-generating electronic components 108, and then distribute the slightly warmed air throughout the first server rack 102 for cooling the air-cooled heat-generating electronic components 128, with heated air being expelled away through the rear side of the first server rack 102.

In turn, the autonomous dual server rack configuration 200 installs the liquid-cooled heat-generating electronic components that are more tolerant to higher operating temperature levels in the second autonomous server rack 202. In particular, the second autonomous server rack 202 incorporates a second heat exchanger 206 mounted on the rear side of the second autonomous server rack 202 and equipped with at least one fan. The rear-mounted heat exchanger 206 operates to pull warmed air from the rear side of the first server rack 102, entering the second server rack 202 at sufficiently low temperature (e.g., does not exceed 35° C. to 42° C.) to cool the air-cooled heat-generating electronic components 228. Flowing air warmed-up by the air-cooled heat-generating electronic components 228 is then pulled by the rear-mounted heat exchanger 206, which cools the cooling liquid heated by the liquid-cooled heat-generating electronic components 208 and expels the warmer air into ambient environment.

The second rear-mounted heat exchanger 206 is equipped with an input (not shown) for receiving warm liquid from the liquid-cooled heat-generating electronic components 208 and an output (not shown) for forwarding recooled liquid back to the liquid-cooled heat-generating electronic components 208. In certain embodiments, the rear air-to-liquid heat exchanger 206 may be embodied as a finned heat exchanger (FHEX). In certain embodiments, air-to-liquid heat exchanger 206 is part of a rear door (e.g., rear door heat exchanger), equipped, for example, with hinges.

The second rear-mounted heat exchanger 206 is fluidly-coupled to a second liquid cooling loop 218 comprising a second circulation conduit 220 that conveys cooling liquid. In particular, the second circulation conduit 220 comprises a forward path 220A fluidly-coupled to the output of the second rear-mounted heat exchanger 206 for forwarding cool/recooled liquid to the liquid-cooled heat-generating electronic components 208 and a return path 220B fluidly-coupled to the input of the second rear-mounted heat exchanger 206 for receiving warmed liquid from the liquid-cooled heat-generating electronic components 208 for recooling operations thereby. The second cooling liquid of the second liquid cooling loop 218 is warmer than the first cooling liquid of the first cooling loop 118.

As such, the second liquid cooling loop 218 is fluidly-coupled to at least one liquid cooling unit 210 that is thermally-mounted on a corresponding heat-generating electronic component 208. The liquid cooling unit 210 is configured with a continuous internal channel that allows for the passage of cooling liquid therethrough.

The second autonomous server rack 202 also incorporates at least one pump 212 to forcibly urge the flow of the cooling liquid along the forward path 220A for supplying the at least one liquid cooling unit 210 with cool/recooled liquid and for urging the flow of warmed liquid along the return path 220B back to the second air-to-liquid heat exchanger 206 for recooling operations. In certain cases, two or more pumps may be implemented and may be arranged in series or parallel configurations. In some embodiments, there is a plurality of liquid cooling units 210 and the forward path 220A and return path 220B include cooling distribution units to fluidly-couple in parallel the liquid cooling units 210 or with a combination of series and parallel arrangement.

Furthermore, in certain cases, at least one plate heat exchanger (PHEX) 230 may be implemented between the first and second liquid cooling loops 118, 218 for cooling improvement and/or safety concerns. The PHEX 230 may be completed by a monitoring of liquid temperatures, actuated valves, and at least one by-pass to adjust the thermal transfer therein.

Therefore, as shown, the autonomous dual server rack configuration 200 provides a cooling configuration that services the cooling needs of two server racks 102, 202 that are abutted against each other. As detailed above, the first server rack 102 incorporates liquid-cooled heat-generating electronic components 108 that are less tolerant of higher operating temperature levels while the second server rack 202 incorporates liquid-cooled heat-generating electronic components 208 that are more tolerant to higher operating temperature levels. For example, some high-temperature-tolerant electronic components 208 may work with liquid inlet temperature up to around 55° C. and/or liquid outlet temperature up to around 60° C. In some embodiments, air-cooled heat-generating electronic components 228 incorporated in the second server rack 202 may also be more tolerant to higher operating temperature levels than air-cooled heat-generating electronic components 128 incorporated in the first server rack 102.

Accordingly, the first server rack 102 employs a front-mounted heat exchanger 106 that pulls in cold ambient air that is distributed throughout the first server rack 102 and flows out of the rear side of the rack 102. The entering air is firstly warmed while flowing across the front-mounted heat exchanger 106 wherein the cooling liquid of the first cooling loop heated by the liquid-cooled heat-generating electronic components 108 is recooled. The air is secondly warmed up while cooling the air-cooled heat-generating electronic components 128 before it exits the first server rack 102 and flows into the front side of the second server rack 202. As the air is then still at sufficiently low temperature, the air flow is still capable of cooling the air-cooled heat-generating electronic components 228. The further heated air flows then across the rear-mounted heat exchanger 206 wherein it gets even hotter while the cooling liquid of the second cooling loop heated by the liquid-cooled heat-generating electronic components 208 is recooled. The hot air is eventually extracted from the second server rack 202 by the rear-mounted heat exchanger 206 that pulls the further heated air away and expels it into the ambient environment. It will be appreciated that the hotter air expelled by the rear-mounted heat exchanger 206 is directed to an area (e.g., a “hot aisle”) that is substantially opposite to, and distanced apart from, the area (e.g., a “cold aisle”) where the front-mounted heat exchanger 106 pulls in cold ambient air.

In some embodiments, the second server rack 202 of the autonomous dual server rack configuration 200 is mechanically divided into a plurality of vertical columns horizontally or vertically adjacent, and the second rear-mounted heat exchanger 206 is a plurality of second rear-mounted heat exchangers 206. For example, in some cases, the second server rack 202 may be arranged with three horizontally adjacent vertical columns, each of them being equipped with a second rear-mounted heat exchanger 206, with the three rear-mounted heat exchangers 206 being fluidly connected in a parallel configuration.

In this manner, the autonomous dual server rack configuration 200 provides a cooling configuration that optimizes, both air cooling and liquid cooling measures for less high-temperature-tolerant liquid-cooled electronic components 108 and higher-temperature-tolerant liquid-cooled electronic components 208, as well as the air-cooled electronic components 128 and 228. As described previously in detail, the cooling measures use a broad range of fluid cooling temperature with the right level of temperature according to each component and their requirements.

In some embodiments, the air and liquid temperatures of the autonomous dual server rack configuration 200, as well as the temperature of the heat-generating electronic components 108, 128, 208, 228 are monitored. In such embodiments, the rotation speed of fans mounted on the heat exchangers 106, 206 and the rotation speed of pumps 112, 212 are controlled to deliver the right flow rates for reaching adapted cooling fluid temperatures and optimizing the cooling of the heat-generating electronic components 108, 128, 208, 228. Besides, in such embodiments, energy usage efficiency may be optimized.

The rack structure 201 of the autonomous dual server rack configuration 200 may be monobloc in some embodiments. In other embodiments, the rack structure 201 could consist of a structure capable of receiving respective sub-structures of the first server rack 102 and the second server rack 202. In some implementations the rack structure 201 is an assembly kit of the juxtaposed respective structures of the first server rack 102 and the second server rack 202 bounded together by binding elements.

Moreover, given the overall architecture of the autonomous dual server rack configuration 200, a contemplated embodiment includes the first and/or second liquid cooling loops supporting the conveyance of a cooling fluid that is capable of changing phase from liquid to gas during absorption of heat, such as, vaporization at the cooling units 110, 210 (i.e., evaporator operations). Commensurately, the cooling fluid is also capable of changing phase from gas back to liquid during the release of heat, such as, condensation at the finned heat exchangers (FHEX) 106, 206 (i.e., condenser operations). In this embodiment, the first and/or second liquid cooling loops benefit from the latent heat capacity that is higher than the specific heat capacity involved in heat transfer by convection.

Relatedly, for the noted contemplated embodiment, the cooling fluid may be selected based on its saturation temperature according to the front or rear positioning within the overall rack structure. For example, if both first and second liquid cooling loops use two-phase cooling fluid, then the saturation temperature of the first cooling fluid will be lower than the saturation temperature of the second cooling fluid. The two cooling loops may also be configured to operate at different pressure levels to adjust their respective boiling points.

Additionally, the first cooling fluid and the second cooling fluid may differ on other fluid characteristics, such as dielectric properties, which could be chosen according to costs, performances, and security considerations.

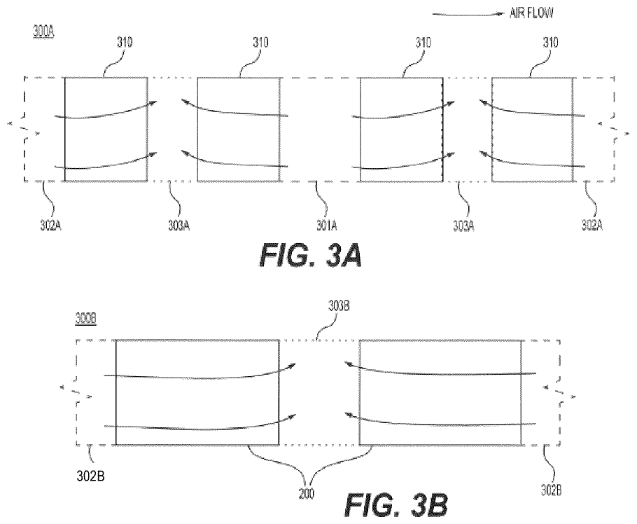

With this said, FIGS. 3A, 3B depict schematic side views of a datacenter room for accommodating two different server rack configurations, in accordance with the embodiments of the present disclosure. The datacenter installation arrangement of multiple racks of dual server rack configuration 200 and the corresponding cold and hot aisles allow a significant reduction of footprint and thus an increase of server density, as the number of aisles is reduced for a same amount of servers. For example, FIG. 3A illustrates four rows of conventional (i.e., non-dual) server racks 310 (e.g., server racks of server rack configuration 100) with two shared hot aisles 303A, one shared cold aisle 301A, and two dedicated half cold aisles 302A. Moreover, FIG. 3B illustrates two rows of server racks of dual server rack configuration 200 incorporating the same number of servers as FIG. 3A, one shared hot aisle 303B and two dedicated half cold aisles 302B. The extension of the configuration depicted on FIG. 3B to more rows of server racks of dual server rack configuration 200 introduces at least one shared cold aisle 301B, the at least one shared cold aisle 301B having the same width as the at least one shared hot aisle 303B, similar to the width of a conventional shared cold aisle 301A. The latter configuration permits a footprint reduction from 15% to 20% compared to conventional footprints.

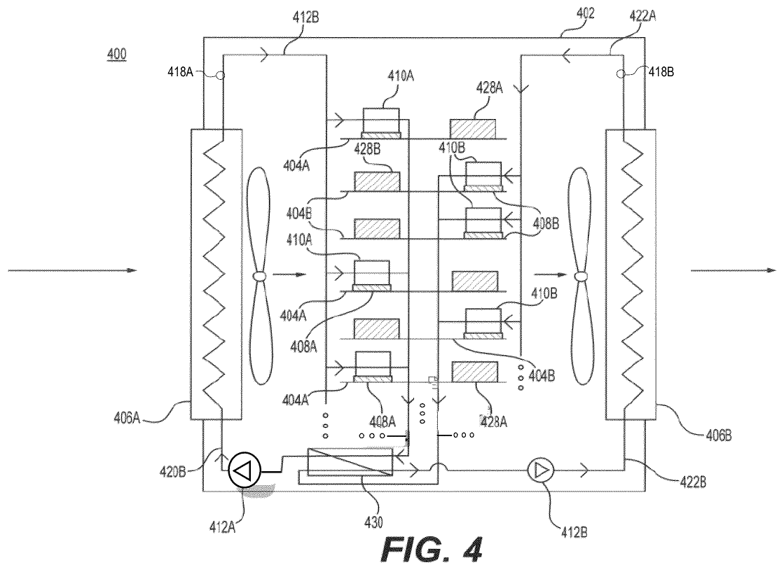

FIG. 4 is a schematic diagram of a side view of an autonomous server rack configuration 400 incorporating a front-mounted heat exchanger 406A servicing a first liquid cooling loop 418A and a rear-mounted heat exchanger 406B servicing a second liquid cooling loop 418B, in accordance with the embodiments of the present disclosure. For purposes of brevity and tractability, operations of the autonomous server rack configuration 400 components that are similar to components detailed above by the previously-disclosed embodiments, will not be repeated unless such components bear on the overall operations of the autonomous server rack 400.

As shown, autonomous server rack configuration 400 comprises a rack structure 402 that houses a first set of rack-mounted processing assemblies 404A containing liquid-cooled heat-generating electronic components 408A that are less tolerant to higher operating temperature levels and a second set of rack-mounted processing assemblies 404B containing liquid-cooled heat-generating electronic components 408B that are more tolerant to higher operating temperature levels. Both set of rack-mounted assemblies 404A, 404B also include air-cooled heat-generating electronic components 428A, 428B.

A first air-to-liquid heat exchanger 406A is mounted on a front side of the rack 402 and equipped with at least one fan. The front-mounted heat exchanger 406A operates to pull in cold ambient air to cool the cooling liquid heated by the liquid-cooled heat-generating electronic components 408A, and then distribute the slightly warmed air throughout the rack 402. The front-mounted heat exchanger 406A is fluidly-coupled to a first liquid cooling loop 418A comprising a first circulation conduit 420 that conveys cooling liquid. In particular, the first circulation conduit 420 comprises a forward path 420A fluidly-coupled to an output of the front-mounted heat exchanger 406A for forwarding cool/recooled liquid to the liquid-cooled heat-generating electronic components 408A and a return path 420B fluidly-coupled to an input of the front-mounted heat exchanger 406A for receiving warmed liquid from the liquid-cooled heat-generating electronic components 408A for recooling operations thereby. The firstly warmed air exiting the front-mounted heat exchanger 406A is at sufficiently low temperature (e.g., does not exceed 30° C. to 37° C.) to cool the air-cooled heat-generating electronic components 428A, 428B.

Each of the liquid-cooled heat-generating electronic components 408A incorporates a liquid cooling unit 410A that is thermally-mounted thereon and is fluidly-coupled to the first liquid cooling loop 418A. The liquid cooling unit 410A is configured with a continuous internal channel that allows for the passage of cooling liquid therethrough, as supplied by the first liquid cooling loop 418A.

The autonomous server rack configuration 400 also incorporates at least one pump 412A to forcibly urge the flow of the cooling liquid along the forward path 420A for supplying the at least one liquid cooling unit 410A with cool/recooled liquid and for urging the flow of warmed liquid along the return path 420B back to the front-mounted heat exchanger 406A for recooling operations. In certain cases, two ore more pumps may be implemented and may be arranged in series or parallel configurations. In some embodiments, there is a plurality of liquid cooling units 410A and the forward path 420A and return path 420B include cooling distribution units to fluidly-couple in parallel the liquid cooling units 410A or with a combination of series and parallel arrangement.

The autonomous server rack configuration 400 further comprises a second air-to-liquid heat exchanger 406B mounted on a rear side of the rack 402 and equipped with at least one fan. The rear-mounted heat exchanger 406B operates to pull air secondly warmed by the air-cooled heat-generating electronic components 428A, 428B to cool the cooling liquid heated by the liquid-cooled heat-generating electronic components 408B, and then expels the hot air into the ambient environment. The rear-mounted heat exchanger 406B is fluidly-coupled to a second liquid cooling loop 418B comprising a second circulation conduit 422 that conveys cooling liquid. In particular, the second circulation conduit 422 comprises a forward path 422A fluidly-coupled to an output of the front-mounted heat exchanger 406B for forwarding cool/recooled liquid to the liquid-cooled heat-generating electronic components 408B and a return path 422B fluidly-coupled to an input of the front-mounted heat exchanger 406B for receiving warmed liquid from the liquid-cooled heat-generating electronic components 408B for recooling operations thereby.

Each of the liquid-cooled heat-generating electronic components 408B incorporates a liquid cooling unit 410B that is thermally-mounted thereon and is fluidly-coupled to the second liquid cooling loop 418B. The liquid cooling unit 410B is configured with a continuous internal channel that allows for the passage of cooling liquid therethrough, as supplied by the second liquid cooling loop 418B.

The autonomous server rack configuration 400 also incorporates at least one pump 412B to forcibly urge the flow of the cooling liquid along the forward path 422A for supplying the at least one liquid cooling unit 410B with cool/recooled liquid and for urging the flow of warmed liquid along the return path 422B back to the rear-mounted heat exchanger 406B for recooling operations. In certain cases, two or more pumps may be implemented and may be arranged in series or parallel configurations. In some embodiments, there is a plurality of liquid cooling units 410B and the forward path 422A and return path 422B include cooling distribution units to fluidly-couple in parallel the liquid cooling units 410B or with a combination of series and parallel arrangement.

Furthermore, in certain cases, a plate heat exchanger (PHEX) 430 may be implemented between the first and second liquid cooling loops 418A, 418B for cooling improvement and/or safety concerns. The PHEX 430 may be completed by a monitoring of liquid temperatures, actuated valves, and at least one by-pass to adjust the thermal transfer therein.

Accordingly, the front-mounted heat exchanger 406A operates to pull in cold ambient air that is distributed throughout the server rack 402 to initially extract heat from the cooling liquid of the first liquid cooling loop warmed by the less high-temperature-tolerant electronic components 408A. The air that is, indirectly, warmed by the liquid-cooled heat-generating electronic components 408A is, in turn heated up by the air-cooled heat-generating electronic components 428A, 428B, used to extract heat from the cooling liquid of the second liquid cooling loop warmed by the more high-temperature-tolerant electronic components 408B, and then extracted from the server rack 402 by the rear-mounted heat exchanger 406B that pulls the warmed air away and expels it into the ambient environment. It will be appreciated that the hot air expelled by the rear-mounted heat exchanger 406B is directed to an area (e.g., a “hot aisle”) that that is substantially opposite to, and distanced apart from, the area (e.g., a “cold aisle”) where the front-mounted heat exchanger 406A pulls in cold ambient air.

In some embodiments, the rack structure 402 of the autonomous server rack configuration 400 is mechanically divided into a plurality of vertical columns horizontally or vertically adjacent, the first front-mounted heat exchanger 406A is a plurality of first front-mounted heat exchangers 406A, and the second rear-mounted heat exchanger 406B is a plurality of second rear-mounted heat exchangers 406B. For example, in some cases, the rack structure 402 may be arranged with three horizontally adjacent vertical columns, each of them being equipped with a first front-mounted heat exchanger 406A and a second rear-mounted heat exchanger 406B, with the three front-mounted heat exchangers 406A being fluidly connected in a parallel configuration, and the three rear-mounted heat exchangers 406B being fluidly connected in a parallel configuration. In certain embodiments, each of the air-to-liquid heat exchangers 406A (resp. 406B) are part of a front (resp. rear door) (e.g., front (resp. rear) door heat exchanger), equipped, for example, with hinges.

In this manner, autonomous server rack configuration 400 provides a cooling configuration that optimizes, both air cooling and liquid cooling measures for less high-temperature-tolerant liquid-cooled electronic components 408A and higher temperature tolerant electronic components 408B, as well as the air-cooled electronic components 428A and 428B. As described previously in details, the cooling measures use a broad range of fluid cooling temperature with the right level of temperature according to each component and their requirements.

Furthermore, the autonomous server rack configuration 400 may, at first glance, appear to be more expensive than a conventional rack configuration, since the numbers of heat-exchangers, fans and pumps are higher, but as the heat load to recover from the two liquid cooling loops 418A, 418B is shared between the first front and second rear heat exchangers 406A and 406B, they can be chosen smaller and lighter. Accordingly, the pumps and fans can also be smaller and less energy consuming, as their operating points may require lower flow rate and/or lower pressure increase.

In some embodiments, the air and liquid temperatures of the autonomous server rack configuration 400, as well as the temperature of the heat-generating electronic components 408A, 428A, 408B, 428B are monitored. In such embodiments, the rotation speed of fans mounted on the heat exchangers 406A, 406B and the rotation speed of pumps 412A, 412B are controlled to deliver the right flow rates for reaching adapted cooling fluid temperatures and optimizing the cooling of the heat-generating electronic components 408A, 428A, 408B, 428B. Besides, in such embodiments, energy usage efficiency may be optimized.

In alternative embodiments, the rack-mounted processing assemblies 404A and 404B have their own integrated compact fans and these ones may be powerful enough for assuring a contribution to the air flow with a sufficient static pressure to allow the removal of the at least one fan for the first air-to-liquid heat exchanger 406A or for the second air-to-liquid heat exchanger 406B. In such embodiments, if the air-to-liquid heat exchangers 406A and 406B are respectively part of a front door and a rear door, the air-to-liquid heat exchanger equipped with at least one fan is then part of an active (front or rear) door heat exchanger, while the air-to-liquid heat exchanger without fan is part of a passive (front or rear) door heat exchanger.

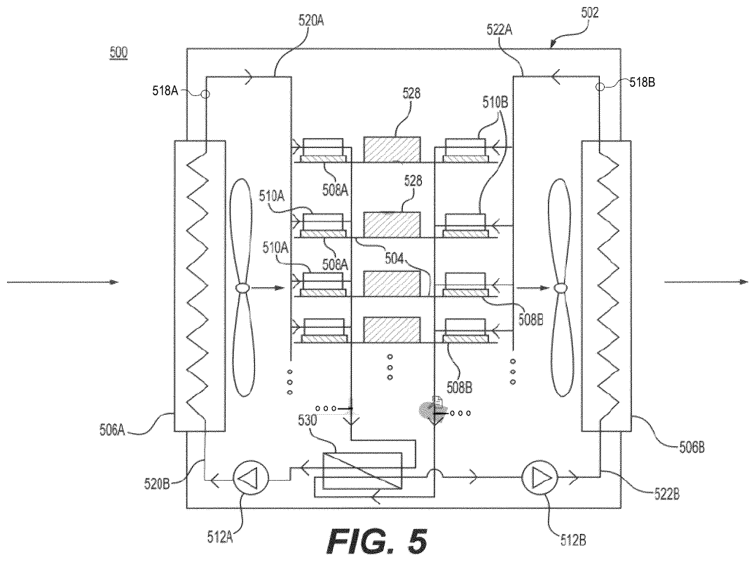

FIG. 5 is a schematic diagram of a side view of an autonomous server rack configuration 500 similar to the autonomous server rack configuration 400 incorporating a front-mounted heat exchanger 506A servicing a first liquid cooling loop 518A and a rear-mounted heat exchanger 506B servicing a second liquid cooling loop 518B, in accordance with the embodiments of the present disclosure. For purposes of brevity and tractability, operations of the autonomous server rack configuration 500 components that are similar to components detailed above by the previously-disclosed embodiments, will not be repeated unless such components bear on the overall operations of the autonomous server rack 500.

As shown, autonomous server rack configuration 500 comprises a rack structure 502 that houses a set of rack-mounted processing assemblies 504 containing both a first set of liquid-cooled heat-generating electronic components 508A that are less tolerant to higher operating temperature levels and a second set of liquid-cooled heat-generating electronic components 508B that are more tolerant to higher operating temperature levels. For example, the liquid-cooled heat-generating electronic components 508A and 508B could be two different kind of electronic devices like CPUs and GPUs, or vice versa, with different thermal requirements. The rack-mounted assemblies 504 also include air-cooled heat-generating electronic components 528.

As such, each of the rack-mounted processing assemblies 504 includes two pairs of hydraulic connections, one pair connected to a first liquid cooling loop 518A, and the other pair connected to a second liquid cooling loop 518B. Thus, the first liquid cooling loop 518A comprises the first front-mounted heat exchanger 506A, the first circulation conduit 520, the forward path 520A, the return path 520B, the at least one first pump 512A, and the at least one liquid cooling unit 510A thermally-mounted onto the at least one high-temperature sensitive liquid-cooled heat-generating electronic components 508A. Similarly, the second liquid cooling loop 518B comprises the second rear-mounted heat exchanger 506B, the second circulation conduit 522, the forward path 522A, the return path 522B, the at least one second pump 512B, and the at least one liquid cooling unit 510B thermally-mounted onto the at least one high-temperature temperature liquid-cooled heat-generating electronic components 508B. In some embodiments, some rack-mounted processing assemblies 504 may comprise only liquid-cooled heat-generating electronic components 508A (resp. 508B) without liquid-cooled heat-generating electronic components 508B (resp. 508A). Additionally, some rack-mounted processing assemblies 504 may incorporate a plurality of liquid cooling units 510A (resp. 510B) and, in such cases, may also include integrated smaller cooling distribution units to fluidly-couple in parallel the corresponding liquid cooling units 510A (resp. 510B) or with a combination of series and parallel arrangement.

Furthermore, in certain cases, a plate heat exchanger (PHEX) 530 may be implemented between the first and second liquid cooling loops 518A, 518B for cooling improvement and/or safety concerns. All detailed implementations previously described for the autonomous server rack configuration 400 are applicable to the autonomous server rack configuration 500.

Modifications and improvements to the above-described implementations of the present technology may become apparent to those skilled in the art. The foregoing description is intended to be exemplary rather than limiting. The scope of the present technology is therefore intended to be limited solely by the scope of the appended claims.

What is claimed is:

1. An autonomous rack system having rack structures with self-contained liquid cooling loops for installation in various environments, comprising:
a first rack structure housing a first set of rack-mounted processing assemblies containing liquid-cooled heat-generating electronic components and air-cooled heat-generating electronic components, the first rack structure having a front side and an opposing rear side;
a first air-to-liquid heat exchanger mounted to the front side of the first rack structure and configured to pull in cold ambient air towards the first set of rack-mounted processing assemblies;
a first liquid cooling loop, comprising:
a circulation conduit conveying cooling liquid incorporating a forward path fluidly-coupled to an output of the first air-to-liquid heat exchanger and a return path fluidly-coupled to an input of the first air-to-liquid heat exchanger;
at least one liquid cooling unit thermally mounted onto the at least one liquid-cooled heat-generating electronic component of the first set of processing assemblies and fluidly-coupled to the circulation conduit to internally channel the cooling liquid therethrough; and
at least one first pump to forcibly urge the flow of the cooling liquid through the forward path, the liquid cooling unit, the return path, and the first air-to-liquid heat exchanger;
wherein:
the cold ambient air pulled into the front side of the first rack structure by the first air-to-liquid heat exchanger is firstly warmed while cooling the first cooling liquid, flows across the first set of processing assemblies, such that the air secondly warmed by the air-cooled heat-generating electronic components of the first set of processing assemblies is expelled from the rear side of the first rack structure;
along the forward path, the liquid cooling unit receives the cooling liquid from the output of the first air-to-liquid heat exchanger for internally channeling the cooling liquid therein; and
along the return path, the liquid cooling unit returns the internally channeled liquid after being warmed by the liquid-cooled heat-generating electronic components of the first set of processing assemblies to the input of the first air-to-liquid heat exchanger;
a second rack structure juxtaposedly positioned at the rear of the first rack structure, the second rack structure housing a second set of rack-mounted processing assemblies containing air-cooled heat-generating electronic components, and liquid-cooled heat-generating electronic components having operating thermal requirements that are more tolerant to higher temperature levels than the liquid-cooled heat-generating electronic components of the first set of rack-mounted processing assemblies;
a second air-to-liquid heat exchanger mounted to the rear side of the second rack structure and configured to pull away warmed air from the second set of rack-mounted processing assemblies and expel the hot air from the rear side of the second rack structure;
a second liquid cooling loop, comprising:
a second circulation conduit conveying cooling liquid incorporating a forward path fluidly-coupled to an output of the second air-to-liquid heat exchanger and a return path fluidly-coupled to an input of the second air-to-liquid heat exchanger;
at least one liquid cooling unit thermally mounted onto the at least one liquid-cooled heat-generating electronic component of the second set of processing assemblies and fluidly-coupled to the circulation conduit to internally channel the cooling liquid; and
at least one second pump to forcibly urge the flow of the cooling liquid through the forward path, the liquid cooling unit, the return path, and the second air-to-liquid heat exchanger;
wherein:
the warm air expelled from the first set of processing assemblies flows across the second set of rack-mounted processing assemblies, such that the air warmed-up by the air-cooled heat-generating components of the second set of rack-mounted processing assemblies is expelled from the rear side of the second rack structure by the second air-to-liquid heat exchanger, where the expelled air gets warmer while cooling the second cooling liquid;
the second cooling liquid of the second liquid cooling loop is warmer than the first cooling liquid of the first liquid cooling loop;
along the forward path, the liquid cooling unit receives the liquid from the output of the second air-to-liquid heat exchanger for internally channeling the liquid therein; and
along the return path, the liquid cooling unit returns the internally channeled liquid after being warmed by the liquid-cooled heat-generating electronic components of the second set of processing assemblies to the input of the second air-to-liquid heat exchanger.

2. The autonomous rack system of claim 1, wherein the at least one first pump comprises two or more pumps arranged in series or parallel configurations.

3. The autonomous rack system of claim 1, wherein the firstly warmed air flowing across the first set of processing assemblies comprises a temperature less than 37° C.

4. The autonomous rack system of claim 1, wherein the first air-to-liquid heat exchanger and/or the second air-to-liquid heat exchanger comprise a finned heat exchanger (FHEX).

5. The autonomous rack system of claim 1, wherein the at least one second pump comprises two or more pumps arranged in series or parallel configurations.

6. The autonomous rack system of claim 1, wherein the warm air expelled from the first set of processing assemblies and directed to flow across the second set of rack-mounted processing assemblies comprises a temperature less than 42° C.

7. The autonomous rack system of claim 1, further comprising at least one plate heat exchanger (PHEX) installed between the first liquid cooling loop return path and the second liquid cooling loop return path.

8. The autonomous rack system of claim 1, wherein:
the air and liquid temperatures are monitored;
the temperature of the heat-generating electronic components are monitored;
each of the first and second heat exchangers comprise fans, in which the rotation speed of the fans are controlled based on the monitored temperatures to provide the proper air flow throughout the first and second rack structures;
the rotation speed of the at least one first and second pumps are controlled based on the monitored temperatures to deliver the right liquid flow rates for the first and second liquid cooling loops; and
the monitoring and the combined control of the rotation speeds of fans and pumps permit to reach adapted cooling fluid temperatures and optimize the cooling of the heat-generating electronic components.

9. The autonomous rack system of claim 1, wherein installation of multiple racks comprising the first and second rack structures include arranging the first and second rack structures within a datacenter to reduce the number of cold aisles and hot aisles and optimize footprint and server density.

10. An autonomous rack system having rack structures with self-contained liquid cooling loops for installation in various environments, comprising:
a rack structure housing a first set of rack-mounted processing assemblies containing liquid-cooled heat-generating electronic components and air-cooled heat-generating electronic components and a second set of rack-mounted processing assemblies containing air-cooled heat-generating electronic components and liquid-cooled heat-generating electronic components having operating thermal requirements that are more tolerant to higher temperature levels than the liquid-cooled heat-generating electronic components of the first set of rack-mounted processing assemblies;
a first air-to-liquid heat exchanger mounted to a front side of the rack structure and configured to pull in cold ambient air towards the first set of rack-mounted processing assemblies;
a second air-to-liquid heat exchanger mounted to a rear side of the rack structure and configured to pull away warmed air from the second set of rack-mounted processing assemblies and expel the hot air from the rear side of the rack structure;
a first liquid cooling loop, comprising:
a first circulation conduit conveying cooling liquid incorporating a forward path fluidly-coupled to an output of the first air-to-liquid heat exchanger and a return path fluidly-coupled to an input of the first air-to-liquid heat exchanger;
at least one liquid cooling unit thermally mounted onto the at least one liquid-cooled heat-generating electronic component of the first set of processing assemblies and fluidly-coupled to the circulation conduit to internally channel the cooling liquid therethrough; and
at least one first pump to forcibly urge the flow of the cooling liquid through the forward path, the liquid cooling unit, the return path, and the first air-to-liquid heat exchanger;
a second liquid cooling loop, comprising:
a second circulation conduit conveying cooling liquid incorporating a forward path fluidly-coupled to an output of the second air-to-liquid heat exchanger and a return path fluidly-coupled to an input of the second air-to-liquid heat exchanger;
at least one liquid cooling unit thermally mounted onto the at least one liquid-cooled heat-generating electronic component of the second set of processing assemblies and fluidly-coupled to the circulation conduit to internally channel the cooling liquid therethrough; and
at least one second pump to forcibly urge the flow of the cooling liquid through the forward path, the liquid cooling unit, the return path, and the second air-to-liquid heat exchanger;
wherein:
the cold ambient air pulled into the front side of the rack structure by the first air-to-liquid heat exchanger, is firstly warmed while cooling the first cooling liquid of the first liquid cooling loop and flows across the first and second sets of processing assemblies, such that the air warmed by the air-cooled heat-generating electronic components of the first and second sets of processing assemblies is expelled from the rear side of the rack structure by the second air-to-liquid heat exchanger, where the expelled air gets warmer while cooling the second cooling liquid of the second liquid cooling loop;
the second cooling liquid of the second liquid cooling loop is warmer than the first cooling liquid of the first liquid cooling loop;
along the forward path of the first circulation conduit, the liquid cooling unit receives the cooling liquid from the output of the first air-to-liquid heat exchanger for internally channeling the cooling liquid therein and along the return path, the liquid cooling unit returns the internally channeled liquid after being warmed by the liquid-cooled heat-generating electronic components of the first set of processing assemblies to the input of the first air-to-liquid heat exchanger; and
along the forward path of the second circulation conduit, the liquid cooling unit receives the cooling liquid from the output of the second air-to-liquid heat exchanger for internally channeling the cooling liquid therein and along the return path, the liquid cooling unit returns the internally channeled liquid after being warmed by the liquid-cooled heat-generating electronic components of the second set of processing assemblies to the input of the second air-to-liquid heat exchanger.

11. The autonomous rack system of claim 10, wherein the at least one first pump and/or the at least one second pump comprise two or more pumps arranged in series or parallel configurations.

12. The autonomous rack system of claim 10, further comprising at least one plate heat exchanger (PHEX) installed between the first liquid cooling loop return path and the second liquid cooling loop return path.

13. The autonomous rack system of claim 10, wherein the warm air expelled from the first air-to-liquid heat exchanger directed to flow across the first and second set of rack-mounted processing assemblies comprises a temperature less than 37° C.

14. The autonomous rack system of claim 10, wherein the first air-to-liquid heat exchanger and/or the second air-to-liquid heat exchanger comprise a finned heat exchanger (FHEX).

15. A rack structure housing a set of rack-mounted processing assemblies that include air-cooled heat-generating electronic components, a first set of liquid-cooled heat-generating electronic components, and a second set of liquid-cooled heat-generating electronic components, in which the second set of liquid-cooled heat-generating electronic components manifest operating thermal requirements that are more tolerant to the higher temperature levels than the first set of liquid-cooled heat-generating electronic components, the rack structure comprising:
a first air-to-liquid heat exchanger mounted to a front side of the rack structure and configured to pull in cold ambient air towards the set of rack-mounted processing assemblies;
a second air-to-liquid heat exchanger mounted to a rear side of the rack structure and configured to pull away warmed air from the set of rack-mounted processing assemblies and expel the hot air from the rear side of the rack structure;
a first liquid cooling loop, comprising:
a first circulation conduit conveying cooling liquid incorporating a forward path fluidly-coupled to an output of the first air-to-liquid heat exchanger and a return path fluidly-coupled to an input of the first air-to-liquid heat exchanger;
at least one liquid cooling unit thermally mounted onto the at least one first liquid-cooled heat-generating electronic component of the set of processing assemblies and fluidly-coupled to the circulation conduit to internally channel the cooling liquid therethrough; and
at least one first pump to forcibly urge the flow of the cooling liquid through the forward path, the liquid cooling unit, the return path, and the first air-to-liquid heat exchanger;
a second liquid cooling loop, comprising:
a second circulation conduit conveying cooling liquid incorporating a forward path fluidly-coupled to an output of the second air-to-liquid heat exchanger and a return path fluidly-coupled to an input of the second air-to-liquid heat exchanger;
at least one liquid cooling unit thermally mounted onto the at least one second liquid-cooled heat-generating electronic component of the set of processing assemblies and fluidly-coupled to the circulation conduit to internally channel the cooling liquid therethrough; and
at least one second pump to forcibly urge the flow of the cooling liquid through the forward path, the liquid cooling unit, the return path, and the second air-to-liquid heat exchanger;
wherein:
the cold ambient air pulled into the front side of the rack structure by the first air-to-liquid heat exchanger, is firstly warmed while cooling the first cooling liquid of the first liquid cooling loop and flows across the set of processing assemblies, such that the air warmed by the air-cooled heat-generating electronic components of the set of processing assemblies is expelled from the rear side of the rack structure by the second air-to-liquid heat exchanger, where the expelled air gets warmer while cooling the second cooling liquid of the second liquid cooling loop;
the second cooling liquid of the second liquid cooling loop is warmer than the first cooling liquid of the first liquid cooling loop;
along the forward path of the first circulation conduit, the liquid cooling unit receives the cooling liquid from the output of the first air-to-liquid heat exchanger for internally channeling the cooling liquid therein and along the return path, the liquid cooling unit returns the internally channeled liquid after being warmed by the first set of liquid-cooled heat-generating electronic components of the set of processing assemblies to the input of the first air-to-liquid heat exchanger; and
along the forward path of the second circulation conduit, the liquid cooling unit receives the cooling liquid from the output of the second air-to-liquid heat exchanger for internally channeling the cooling liquid therein and along the return path, the liquid cooling unit returns the internally channeled liquid after being warmed by the second set of liquid-cooled heat-generating electronic components of the set of processing assemblies to the input of the second air-to-liquid heat exchanger.
